(19) United States
(12) Patent Application Publication
(10) Pub. No.: US 2013/0168518 A1
(43) Pub. Date: Jul. 4, 2013

(54) MOUNTING APPARATUS FOR POWER SUPPLY

(71) Applicants: WEN-HU LU, Shenzhen City (CN); PO-WEN CHIU, Tu-Cheng (TW); ZHAN-YANG LI, Shenzhen City (CN)

(72) Inventors: WEN-HU LU, Shenzhen City (CN); PO-WEN CHIU, Tu-Cheng (TW); ZHAN-YANG LI, Shenzhen City (CN)

(21) Appl. No.: 13/630,265

(22) Filed: Sep. 28, 2012

(30) Foreign Application Priority Data
Dec. 28, 2011 (CN) 201110447161.1

(51) Int. Cl. H05K 7/14

(52) U.S. Cl. 248/309.1

(57) ABSTRACT

A mounting apparatus includes a chassis and a mounting tray for receiving a power supply. The chassis includes a side plate. The side plate includes a side plate body, a securing flange extending from the side plate body, and a mounting portion extending from the side plate body. The mounting tray includes a positioning portion and an engaging portion. The engaging portion engages the securing flange to prevent the mounting tray from moving along a first direction substantially parallel to the side plate body. The positioning portion defines a positioning space receiving the mounting portion to prevent the mounting tray from moving along a second direction substantially perpendicular to the side plate body. The positioning portion moves along a third direction substantially opposite to the first direction to enable the mounting portion to be received in the positioning space.

### BACKGROUND

1. Technical Field

The present disclosure relates to mounting apparatuses, and particularly to a mounting apparatus for securing a power supply to an electronic device.

2. Description of Related Art

Computer systems can include a main power supply unit and a plurality of supplemental power supplies in a computer case. The supplemental power supplies are used to supply power for electronic components when the main power supply cannot supply sufficient power or shuts down. Supplemental power supplies are mounted with screws, which is inconvenient.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus in accordance with an embodiment.

FIG. 2 is similar to FIG. 1, but viewed from a different aspect.

FIG. 3 is an assembled view of the mounting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

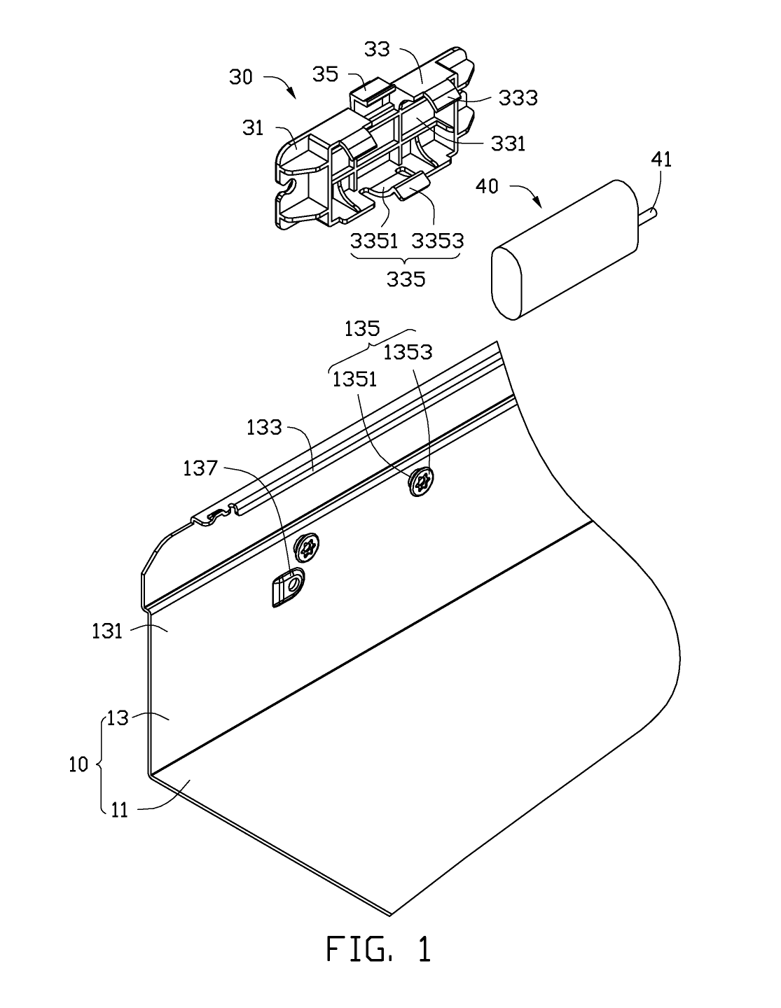

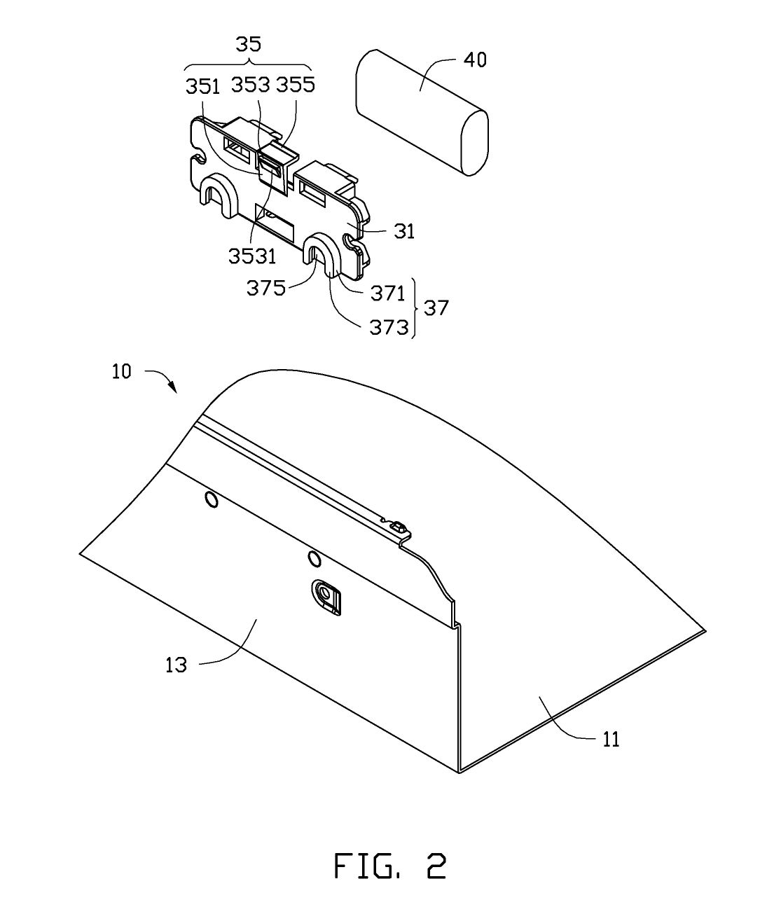

Referring to FIGS. 1 and 2, a mounting apparatus in accordance with an embodiment includes a chassis 10 and a mounting tray 30 attached to the chassis 10. The mounting tray 30 receives a power supply 40. The power supply 40 includes a cable 41. In one embodiment, the power supply 40 is a supplemental power supply.

The chassis 10 includes a bottom plate 11 and a side plate 13, connected to the bottom plate 11. In one embodiment, the side plate 13 is substantially perpendicular to the bottom plate 11. The side plate 13 includes a side plate body 131 and a securing flange 133 extending from the side plate body 131. The side plate 13 further includes a mounting portion 135 extending from the side plate body 131. The mounting portion 135 includes neck portion 1351 extending from the side plate body 131 and a head portion 1353 extending from the neck portion 1351. The cross section area of the head portion 1353 is greater than the cross section area of the neck portion 1351, taken along a plane substantially parallel to the side plate body 131. The side plate 13 further includes a support portion 137 extending from the side plate body 131.

The mounting tray 30 includes a base body 31 and a receiving portion 33 extending from the base body 31. The receiving portion 33 defines a receiving space 331 for receiving the power supply 40. The mounting tray 30 further includes two first securing tabs 333 extending from the receiving portion 33. Each first securing tab 333 is arc-shaped. The mounting tray 30 further includes a second securing tab 335 extending from the receiving portion 33. The second securing tab 335 includes a securing portion 3351 extending from the receiving portion 33 and a handling portion 3353 extending from the securing portion 3351. The securing portion 3351 is arc-shaped. The mounting tray 30 further includes an engaging portion 35 extending from the base body 31. The engaging portion 35 includes a connecting portion 351 extending from the base body 31, an engaging protrusion 353 extending from the connecting portion 351, and a pressing portion 355 extending from the engaging protrusion 353. The engaging protrusion 353 is wedge-shaped. The engaging protrusion 353 defines an inclined surface 3531. The mounting tray 30 further includes two positioning portions 37 extending from the base body 31. Each positioning portion 37 includes a surrounding portion 371 extending from the base body 31 and a stopper flange 373 extending from the surrounding portion 371. The surrounding portion 371 and the stopper flange 373 are both U-shaped. A positioning space 375 is defined in the stopper flange 373 and the base body 31.

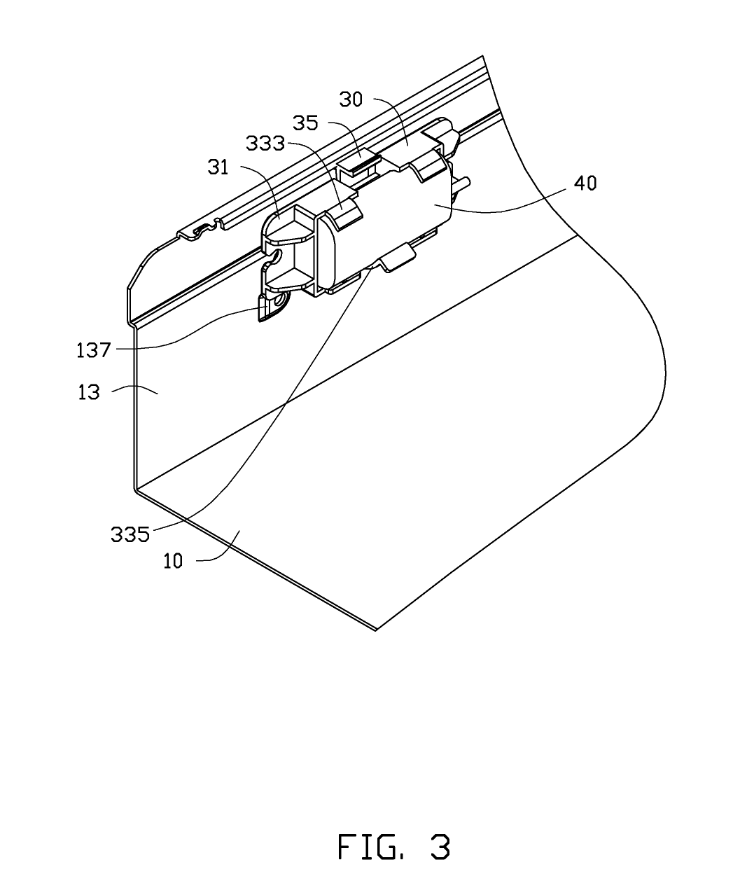

Referring to FIGS. 1-3, in assembly, the handling portion 3353 is pressed to enable the securing portion 3351 to be deformed outward. The power supply 40 is placed in the receiving space 331 of the receiving portion 33. The handling portion 3353 is released and the securing portion 3351 rebounds to resist the upper side of the power supply 40. The two first securing tabs 333 resist the lower side of the power supply 40 to prevent the power supply from moving out of the receiving space 331.

The mounting tray 30 is placed on the inner side of the side plate body 131 and is moved down to enable the two positioning spaces 375 to receive the mounting portions 135. During the process, the inclined surface 3531 of the engaging portion 35 resists the inner side of the securing flange 133 enabling the connecting portion 351 to be deformed. The connecting portion 351 is released to drive the engaging protrusion 353 to engage the securing flange 133, when the engaging protrusion 353 is aligned with the edge of the securing flange 133. Thereby the mounting tray 30 is prevented from moving upward. The mounting portions 135 are received in the positioning portions 37. The stopper flanges 373 of the positioning portions 37 prevent the mounting tray 30 from moving along a direction substantially perpendicular to the side plate body 131. The base body 31 is placed on the support portion 137.

In disassembly of the power supply 40, the handling portion 3353 of the second securing tab 335 is pressed to enable the securing portion 3351 to be deformed. Then the power supply 40 can be easily removed from the receiving portion 33. In disassembly of the mounting tray 30, the pressing portion 355 is pressed to drive the engaging protrusion 353 to disengage from the securing flange 133. The mounting tray 30 is moved upward and removed from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a chassis comprising a side plate; the side plate comprising a side plate body, a securing flange extending from the side plate body, and a mounting portion extending from the side plate body; and
a mounting tray for receiving a power supply, the mounting tray comprises a positioning portion and an engaging portion; the engaging portion engages the securing flange to prevent the mounting tray from moving along a first direction that is substantially parallel to the side plate body; the positioning portion defines a positioning space receiving the mounting portion to prevent the mounting tray from moving along a second direction that is substantially perpendicular to the side plate body; and the positioning portion configured to move along a third direction that is substantially opposite to the first direction, to enable the mounting portion to be received in the positioning space.

2. The mounting apparatus of claim 1, wherein the mounting tray comprises a base body; the positioning portion extends from the base body; the positioning portion comprises a surrounding portion extending from the base body and a stopper flange extending from the surrounding portion; and the stopper flange is configured to prevent the mounting portion from moving along the second direction.

3. The mounting apparatus of claim 2, wherein the mounting portion comprises a neck portion extending from the side plate body and a head portion extending from the neck portion; a cross section of the head portion is greater than a cross section of the neck portion, taken along a plane substantially parallel the side plate body; and the head portion is received in the positioning space and is located between the stopper flange and the base body.

4. The mounting apparatus of claim 2, wherein the surrounding portion is U-shaped.

5. The mounting apparatus of claim 1, wherein the engaging portion comprises a connecting portion, an engaging protrusion extending from the connecting portion, and a pressing portion extending from the engaging protrusion; the engaging protrusion engages the securing flange; the engaging protrusion is wedge-shaped; and the pressing portion is configured to drive the engaging protrusion to disengage from the securing flange.

6. The mounting apparatus of claim 1, wherein the mounting tray comprises a base body and a receiving portion, extending from an inner side of the base body; the positioning portion extends from an outer side of the base body; and the receiving portion defines a receiving space configured to receive the power supply.

7. The mounting apparatus of claim 6, wherein the mounting tray further comprises a securing tab extending from the receiving portion; and the securing tab is configured to resist the power supply to prevent the power supply from moving out of the receiving space.

8. The mounting apparatus of claim 7, wherein the securing tab is arc-shaped.

9. The mounting apparatus of claim 6, wherein the mounting tray further comprises a securing tab extending from the receiving portion; the securing tab comprises a securing portion extending from the receiving portion and a handling portion extending from the securing portion; the securing portion is configured to resist the power supply to prevent the power supply from moving out of the receiving space; and the handling portion is configured to drive the securing portion to move outward.

10. The mounting apparatus of claim 1, wherein the side plate further comprises a support portion extending from the side plate body, and the mounting tray is placed on the support portion to be prevented from moving along the third direction.

11. A mounting apparatus comprising:
a chassis comprising a side plate; the side plate comprises a side plate body and a mounting portion extending from the side plate body; the mounting portion comprises a neck portion extending from the side plate body and a head portion extending from the neck portion; and a cross section of the head portion greater than a cross section of the neck portion taken along a plane substantially parallel the side plate body; and
a mounting tray, the mounting tray comprises a base body, a receiving portion extending from an inner side of the base body for receiving a power supply, and a positioning portion extending from an outer side of the base body; the positioning portion defines a positioning space receiving the head portion to prevent the mounting tray from moving along a first direction substantially perpendicular to the side plate body and along a second direction that is substantially parallel to the side plate body; and the positioning portion is configured to move along a third direction that is substantially opposite to the second direction, to enable the head portion to be received in the positioning space.

12. The mounting apparatus of claim 11, wherein the positioning portion comprises a surrounding portion extending from the base body and a stopper flange extending from the surrounding portion; and the stopper flange is configured to prevent the mounting portion from moving along the first direction.

13. The mounting apparatus of claim 12, wherein the head portion is located between the stopper flange and the base body.

14. The mounting apparatus of claim 12, wherein the surrounding portion is U-shaped.

15. The mounting apparatus of claim 11, wherein the mounting tray further comprises an engaging portion extending from the base body; the engaging portion comprises a connecting portion, an engaging protrusion extending from the connecting portion, and a pressing portion extending from the engaging protrusion; the side plate further comprises a securing flange extending from the side plate body; the engaging protrusion engages the securing flange to prevent the mounting tray from moving along the second direction; the engaging protrusion is wedge-shaped; and the pressing portion is configured to drive the engaging protrusion to disengage from the securing flange.

16. The mounting apparatus of claim 11, wherein the receiving portion defines a receiving space configure to receive the power supply.

17. The mounting apparatus of claim 16, wherein the mounting tray further comprises a securing tab extending from the receiving portion; the securing tab is configured to resist the power supply to prevent the power supply from moving out of the receiving space.

18. The mounting apparatus of claim 17, wherein the securing tab is arc-shaped.

19. The mounting apparatus of claim 16, wherein the mounting tray further comprise a securing tab extending from the receiving portion; the securing tab comprises a securing portion extending from the receiving portion and a handling portion extending from the securing portion; the securing portion is configured to resist the power supply to prevent the power supply from moving out of the receiving space; and the handling portion is configured to drive the securing portion to move outward for removing the power supply from the receiving portion.

20. The mounting apparatus of claim 11, wherein the side plate further comprises a support portion extending from the side plate body, and the mounting tray is placed on the support portion to be prevented from moving along the third direction.
